(19) United States
(12) Patent Application Publication
(10) Pub. No.: US 2024/0356465 A1
(43) Pub. Date: Oct. 24, 2024

(54) ELECTROSTATIC CHUCK

(71) Applicant: TOTO LTD., Fukuoka (JP)

(72) Inventors: Masafumi IKEGUCHI, Fukuoka (JP); Kouta KOBAYASHI, Fukuoka (JP); Yutaka MOMIYAMA, Fukuoka (JP)

(73) Assignee: TOTO LTD., Fukuoka (JP)

(21) Appl. No.: 18/635,344

(22) Filed: Apr. 15, 2024

(30) Foreign Application Priority Data
Apr. 24, 2023 (JP) 2023-070804
Aug. 31, 2023 (JP) 2023-141339

(51) Int. Cl. H02N 13/00; B23Q 3/15

(52) U.S. Cl. CPC H02N 13/00; B23Q 3/15

(57) ABSTRACT

An electrostatic chuck 10 includes: a dielectric substrate 100; a base plate 200 formed of a metal material; and a joining layer 300 which is provided between the dielectric substrate 100 and the base plate 200. When a thickness of the joining layer 300 is T (μm) and a Young's modulus of the joining layer 300 at −100° C. is E (MPa), a condition expressed as E≤0.04×T−0.04 is satisfied.

### CROSS-REFERENCE TO RELATED APPLICATION

This application is based upon and claims the benefit of priority from Japanese Patent Applications No. 2023-070804 filed on Apr. 24, 2023 and No. 2023-141339 filed on Aug. 31, 2023, the entire contents of which are incorporated herein by reference.

### BACKGROUND OF THE INVENTION

### Field of the Invention

The present invention relates to an electrostatic chuck.

### Description of the Related Art

Semiconductor manufacturing equipment such as a CVD device is provided with an electrostatic chuck as a device for attracting and holding a substrate such as a silicon wafer to be a processing object. The electrostatic chuck includes a dielectric substrate provided with an attracting electrode and a base plate which supports the dielectric substrate and is configured such that the dielectric substrate and the base plate are joined to each other. While an attracting electrode is generally built into a dielectric substrate, there are cases where a base plate made of metal is used as an attracting electrode. When voltage is applied to the attracting electrode, an electrostatic force is generated and a substrate placed on the dielectric substrate is attracted and held.

Due to exposure to plasma during processing, a temperature of the substrate rises and a temperature of the dielectric substrate also rises. On the other hand, since a low-temperature refrigerant is supplied to the base plate, a temperature of the base plate may drop to −60° C. or to an even lower temperature than −60° C. A large thermal stress is applied to the dielectric substrate due to the temperature change in respective sections, a temperature difference between the dielectric substrate and the base plate, and the like which accompany processing of the substrate.

In order to prevent damage to the dielectric substrate due to thermal stress, a material with appropriate physical properties must be selected as a material of a joining layer which connects the dielectric substrate and the base plate to each other. For example, Japanese Patent Laid-Open No. 2020-23088 proposes setting a storage elastic modulus of a joining layer (adhesive member) at −60° C. to 100 MPa or lower and the like.

Using a material with the lowest possible Young's modulus as the material of the joining layer enables thermal stress that is applied to the dielectric substrate to be reduced. However, in consideration of heat-transfer performance and the like that are required of the joining layer, the Young's modulus of the joining layer cannot be reduced in an unlimited manner. The material of the joining layer must be appropriately selected in consideration of required heat-transfer performance and the like under a condition that the Young's modulus is equal to or lower than a predetermined upper limit value.

The thicker the joining layer, the smaller the thermal stress applied to the dielectric substrate. Therefore, by making the joining layer thicker, the upper limit value of the Young's modulus of the joining layer can be increased. In this manner, the “thickness of the joining layer” and the “upper limit value of the Young's modulus of the joining layer” are parameters that are correlated to each other.

However, in consideration of heat-transfer performance and the like that are required of the joining layer, the joining layer cannot be made thicker in an unlimited manner. In order to suppress thermal stress that is applied to the dielectric substrate while satisfying required specifications such as heat-transfer performance, the “thickness of the joining layer” and the “upper limit value of the Young's modulus of the joining layer” must be appropriately set while taking the correlation between the respective parameters into consideration. However, detailed studies on how to take such correlations into consideration have never been conducted.

The present invention has been made in consideration of the problem described above and an object thereof is to provide an electrostatic chuck which enables a thickness and a Young's modulus of a joining layer to be set to appropriate values and which is capable of reducing thermal stress that is applied to a dielectric substrate.

### SUMMARY OF THE INVENTION

In order to solve the problem described above, an electrostatic chuck according to the present invention includes: a dielectric substrate; a base plate formed of a metal material; and a joining layer which is provided between the dielectric substrate and the base plate. When a thickness of the joining layer is T (μm) and a Young's modulus of the joining layer at −100° C. is E (MPa), a condition expressed as E≤0.04×T−0.04 is satisfied.

Experiments and the like carried out by the present inventors have led to a finding that setting the thickness and the Young's modulus of the joining layer so as to satisfy the condition expressed as E≤0.04×T−0.04 enables thermal stress of the dielectric substrate during processing and the like to be sufficiently reduced. Therefore, by configuring the electrostatic chuck as described above, the thermal stress that is applied to the dielectric substrate can be reduced while setting the thickness and the Young's modulus of the joining layer to appropriate values.

In addition, in the electrostatic chuck according to the present invention, a through hole is also preferably formed in the dielectric substrate.

A through hole is often formed in a dielectric substrate of an electrostatic chuck for the purpose of supplying an inert gas between the dielectric substrate and a substrate and the like. In such a case, thermal stress tends to increase particularly in a portion in a vicinity of a substrate-side end of the through hole. By setting the thickness and the Young's modulus of the joining layer so as to satisfy the condition expressed as E≤0.04×T−0.04, the thermal stress can be suppressed to a level at which damage to the dielectric substrate does not occur even when a through hole is formed in the dielectric substrate.

In addition, in the electrostatic chuck according to the present invention, a diameter at an end of the through hole on an opposite side to the joining layer is also preferably equal to or smaller than 0.2 mm.

The smaller the diameter at the end of the through hole on the opposite side to the joining layer (in other words, a substrate-side end), the larger the thermal stress that is generated in the dielectric substrate. A through hole designed to supply an inert gas is often a small hole with a diameter equal to or smaller than 0.2 mm in order to prevent a dielectric breakdown. By selecting the material of the joining layer so as to satisfy the condition expressed as E≤0.04×T−0.04, the thermal stress can be suppressed to a level at which damage to the dielectric substrate does not occur even when the diameter of the through hole is equal to or smaller than 0.2 mm as described above.

In addition, in the electrostatic chuck according to the present invention, the thickness of the joining layer is also preferably equal to or smaller than 100 μm.

The thinner the joining layer, the larger the thermal stress that is applied to the dielectric substrate. However, even when the thickness of the joining layer is reduced to 100 μm or less, by selecting the material of the joining layer so as to satisfy the condition expressed as E≤0.04×T−0.04, the thermal stress can be suppressed to a level at which damage to the dielectric substrate does not occur.

Furthermore, in the electrostatic chuck according to the present invention, the joining layer is also preferably a layer generated by curing a silicone adhesive.

Forming the joining layer by selecting a silicone adhesive that satisfies the condition expressed as E≤0.04×T−0.04 from among various types of silicone adhesives enables damage to the dielectric substrate due to thermal stress to be prevented.

### Advantageous Effect of Invention

According to the present invention, an electrostatic chuck which enables a thickness and a Young's modulus of a joining layer to be set to appropriate values and which is capable of reducing thermal stress that is applied to a dielectric substrate can be provided.

### BRIEF DESCRIPTION OF THE DRAWINGS

FIG. 1 is a sectional view schematically showing a configuration of an electrostatic chuck according to a present embodiment;

FIG. 2 is a diagram showing a configuration of a dielectric substrate included in the electrostatic chuck shown in FIG. 1;

FIG. 3 is a diagram showing a relationship between a Young's modulus of a joining layer and a maximum stress that is generated in the dielectric substrate; and

FIG. 4 is a diagram showing a relationship between a thickness of the joining layer and an acceptable Young's modulus.

### DETAILED DESCRIPTION OF THE PREFERRED EMBODIMENT

Hereinafter, an embodiment of the present invention will be described with reference to the accompanying drawings. In order to facilitate understanding of the description, same constituent elements in the respective drawings will be denoted by same reference signs whenever possible and redundant descriptions will not be repeated.

An electrostatic chuck 10 according to the present embodiment attracts a substrate W to be a processing object using an electrostatic force and holds the substrate W inside semiconductor manufacturing equipment (not illustrated) such as a CVD film deposition device. For example, the substrate W is a silicon wafer. The electrostatic chuck 10 may be used in devices other than semiconductor manufacturing equipment.

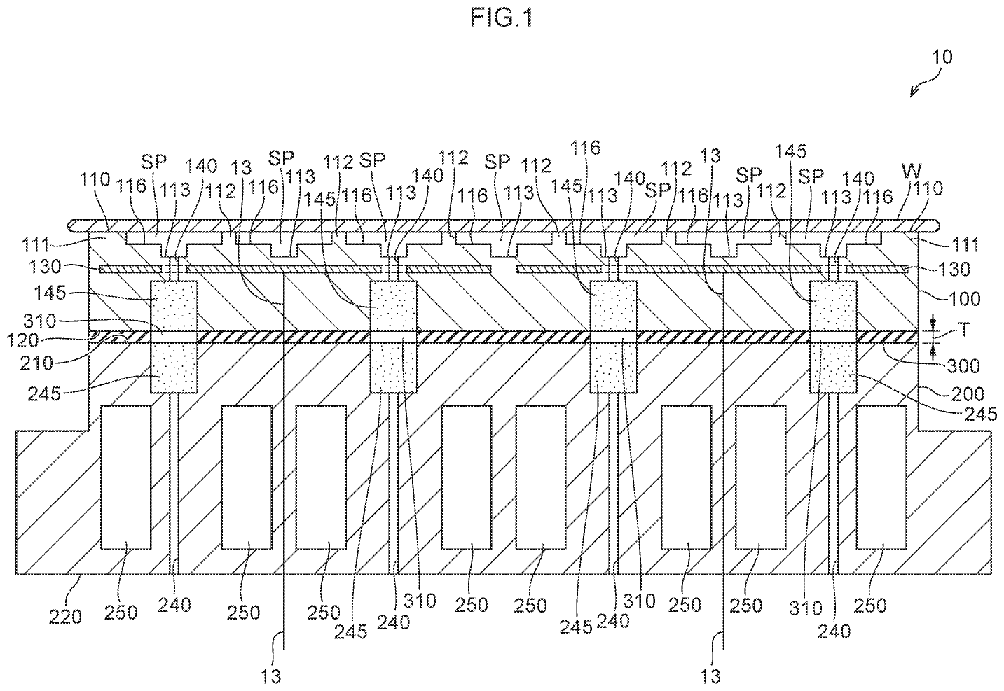

FIG. 1 shows a configuration of the electrostatic chuck 10 in a state where the substrate W has been attracted and is held as a schematic sectional view. The electrostatic chuck 10 includes a dielectric substrate 100, a base plate 200, and a joining layer 300.

The dielectric substrate 100 is an approximately disk-shaped member made of a ceramic sintered compact. While the dielectric substrate 100 includes, for example, high-grade aluminum oxide (Al₂O₃), the dielectric substrate 100 may include other materials. A purity, a type, an additive, and the like of ceramics in the dielectric substrate 100 can be appropriately set in consideration of plasma resistance and the like which are required of the dielectric substrate 100 in the semiconductor manufacturing equipment.

An upper-side surface 110 in FIG. 1 of the dielectric substrate 100 is a “placement surface” on which the substrate W is to be placed. In addition, a lower-side surface 120 in FIG. 1 of the dielectric substrate 100 is a “joined surface” to be joined to the base plate 200 via the joining layer 300 to be described later. Hereinafter, a point of view when viewing the electrostatic chuck 10 from a side of the surface 110 in a direction perpendicular to the surface 110 will also be notated as a “top view”.

An attracting electrode 130 is embedded in the dielectric substrate 100. The attracting electrode 130 is a thin plate-like layer formed of a metal material such as tungsten and is arranged so as to be parallel to the surface 110. As the material of the attracting electrode 130, molybdenum, platinum, palladium, and the like may be used besides tungsten. When voltage is applied to the attracting electrode 130 from outside via a power feed path 13, an electrostatic force is generated between the surface 110 and the substrate W and, accordingly, the substrate W is attracted and held. While two of the attracting electrodes 130 may be provided as so-called “bipolar” electrodes as in the present embodiment, alternatively, only one may be provided as a so-called “monopolar” electrode.

In FIG. 1, an entirety of the power feed path 13 is drawn in a simplified manner. Within the power feed path 13, a portion inside the dielectric substrate 100 is configured as, for example, an elongated via (hole) filled with a conductive material and an electrode terminal (not illustrated) is provided at a lower end thereof. A portion of the power feed path 13 which penetrates the base plate 200 to be described later is a conductive metal member (for example, a busbar) of which one end is connected to the electrode terminal described above. A through hole (not illustrated) for inserting the power feed path 13 is formed in the base plate 200. For example, a cylindrical insulation member may be provided between an inner surface of the through hole and the power feed path 13.

As shown in FIG. 1, a space SP is formed between the dielectric substrate 100 and the substrate W. When processing such as film deposition is performed in the semiconductor manufacturing equipment, helium gas for temperature regulation is supplied to the space SP from outside via a gas hole 140 to be described later or the like. By interposing the helium gas between the dielectric substrate 100 and the substrate W, thermal resistance between the dielectric substrate 100 and the substrate W is regulated and, accordingly, the substrate W is kept at an appropriate temperature. Note that the gas for temperature regulation which is supplied to the space SP may be a gas other than helium.

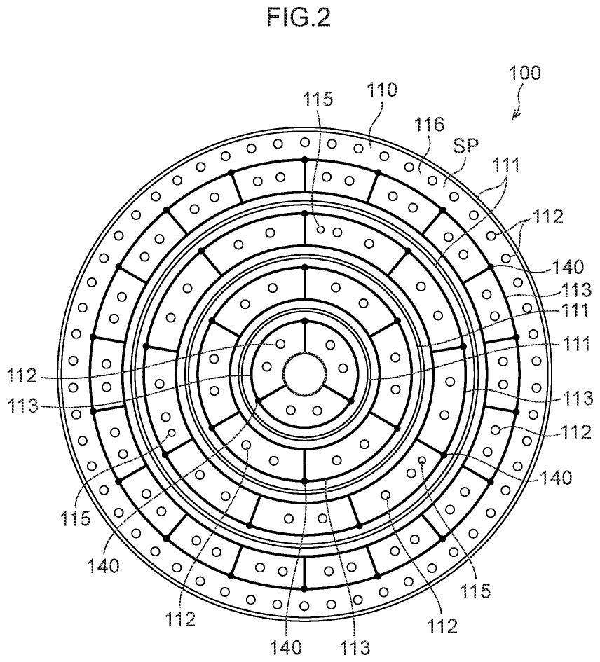

FIG. 2 is a diagram in which the dielectric substrate 100 is drawn in a top view. As shown in FIG. 2, a seal ring 111 and a dot 112 are provided on the surface 110 being a placement surface and the space SP is formed around the seal ring 111 and the dot 112.

The seal ring 111 is a wall which partitions the space SP and the seal ring 111 is provided in plurality so as to be concentrically aligned in a top view. An upper end of each seal ring 111 constitutes a part of the surface 110 and abuts the substrate W. In the present embodiment, four seal rings 111 are provided and, accordingly, the space SP is divided into four parts. Adopting such a configuration enables pressure of helium gas in each space SP to be individually regulated and enables a surface temperature distribution of the substrate W during processing to be made nearly uniform.

In FIGS. 1 and 2, portions denoted by a reference sign “116” are a bottom surface of the space SP. Hereinafter, the portions will also be referred to as the “bottom surface 116”. The seal rings 111 are formed together with the dot 112 to be described next as a result of thinning parts of the surface 110 down to a position of the bottom surface 116.

The dot 112 is a circular projection that protrudes from the bottom surface 116. As shown in FIG. 2, the dot 112 is provided in plurality and arranged so as to be approximately uniformly distributed over the placement surface of the dielectric substrate 100. An upper end of each dot 112 constitutes a part of the surface 110 and abuts the substrate W. Providing the dot 112 described above in plurality suppresses deflection of the substrate W.

A groove 113 is formed on the bottom surface 116 of each space SP. The groove 113 is a groove formed to cause the bottom surface 116 to further retreat towards the side of the surface 120. The groove 113 is formed in order to quickly diffuse the helium gas supplied from the gas hole 140 into the space SP and to make a pressure distribution in the space SP approximately uniform in a short period of time.

The gas hole 140 which perpendicularly extends from the surface 120 toward the side of the surface 110 is formed in the dielectric substrate 100. As shown in FIG. 2, an end of the gas hole 140 on the side of the surface 110 opens on the bottom surface of the groove 113. In the dielectric substrate 100, the gas hole 140 is formed in plurality and the gas holes 140 are arranged along the groove 113. In the present embodiment, a plurality of the gas holes 140 are connected with respect to each of the four divided parts of the space SP.

While a diameter of the gas hole 140 is drawn larger than a width of the groove 113 in FIG. 2 for convenience of illustration, as shown in FIG. 1, the diameter of the actual gas hole 140 is smaller than the width of the groove 113. The width of the groove 113 may be locally increased at positions of the gas hole 140 to ensure that the gas hole 140 fits inside the groove 113.

As shown in FIG. 1, a diameter of the portion of the gas hole 140 on the side of the surface 120 has been expanded as compared to the portion on the side of the surface 110 and a vent plug 145 is arranged inside the gas hole 140. The vent plug 145 is, for example, a porous body formed of alumina and an entirety of the vent plug 145 has ventilation characteristics. Arranging the vent plug 145 described above inside the gas hole 140 enables an occurrence of a dielectric breakdown on a path through the gas hole 140 to be suppressed while securing a flow of gas in the gas hole 140.

In FIG. 2, reference sign “115” denotes a hole into which a lift pin (not illustrated) provided in the semiconductor manufacturing equipment is to be inserted. Hereinafter, the hole will also be referred to as a “lift pin hole 115”. A total of three lift pin holes 115 are formed and arranged so as to be equally spaced at 120-degree intervals. Due to the lift pins that move up and down through the lift pin holes 115, the substrate W is attached to and detached from the surface 110 of the dielectric substrate 100.

The base plate 200 is an approximately disk-shaped member which supports the dielectric substrate 100. For example, the base plate 200 is formed of a metal material such as aluminum. An upper-side surface 210 in FIG. 1 of the base plate 200 is a “joined surface” to be joined to the dielectric substrate 100 via the joining layer 300.

As shown in FIG. 1, a gas hole 240 which perpendicularly extends from the surface 210 towards the side of a surface 220 opposite to the surface 210 is formed in the base plate 200. The gas hole 240 is formed at each position overlapping with the gas hole 140 of the dielectric substrate 100 in a top view and is communicated with the gas hole 140 via a through hole 310 provided in the joining layer 300. Together with the gas hole 140 of the dielectric substrate 100, the gas hole 240 constitutes a part of a path for supplying helium gas towards the space SP.

As shown in FIG. 1, a diameter of a portion of the gas hole 240 on the side of the surface 210 has been expanded as compared to the portion on the side of the surface 220 and a vent plug 245 is arranged inside the gas hole 140. The vent plug 245 is, for example, a porous body formed of alumina and an entirety of the vent plug 245 has ventilation characteristics. Arranging the vent plug 245 as described above inside the gas hole 240 enables an occurrence of a dielectric breakdown on a path through the gas hole 240 to be suppressed while securing a flow of gas in the gas hole 240.

While the gas hole 240 may be formed so that the entire gas hole 240 extends linearly as in the present embodiment, alternatively, the gas hole 240 may be formed so as to bend before reaching the surface 220. In addition, a configuration may be adopted in which after consolidating a plurality of the gas holes 240 on the side of the surface 210 into a small number of flow paths inside the base plate 200, the flow paths are extended to the side of the surface 220.

A refrigerant flow path 250 for supplying a refrigerant is formed inside the base plate 200. When processing such as film deposition is performed in the semiconductor manufacturing equipment, the refrigerant is supplied to the refrigerant flow path 250 from the outside and the base plate 200 is cooled by the refrigerant. Heat generated on the substrate W during the processing is transferred to the refrigerant via the helium gas in the space SP, the dielectric substrate 100, and the base plate 200 and discharged to the outside together with the refrigerant.

In the base plate 200, a through hole (not illustrated) for passing a lift pin therethrough is formed at each of the positions that overlap with the lift pin holes 115 in a top view.

An insulator film may be formed on the surface of the base plate 200. The insulator film is preferably formed on the surface of the base plate 200 in a range including at least an entirety of the surface 210. As the insulator film, for example, a film of alumina formed by spraying can be used. Covering the surface of the base plate 200 with the insulator film enables dielectric strength of the base plate 200 to be increased.

The joining layer 300 is a layer provided between the dielectric substrate 100 and the base plate 200 to join the dielectric substrate 100 and the base plate 200 to each other. The joining layer 300 is generated by curing an adhesive made of an insulating material. In the present embodiment, a silicone adhesive is used as the adhesive. However, the joining layer 300 may be a layer obtained by curing an adhesive of other types. In any case, a material of which thermal conductivity is as high as possible is preferably used as the material of the joining layer 300 so that thermal resistance between the dielectric substrate 100 and the base plate 200 decreases.

The dielectric substrate 100 is joined to the base plate 200 in a state where the surface 120 is parallel to the surface 210 of the base plate 200. Therefore, a thickness of the joining layer 300 is uniform over the entire joining layer 300. Hereinafter, a numerical value representing the thickness of the joining layer 300 in units of “μm” will be notated as “T”. For example, when the thickness of the joining layer 300 is 0.1 mm, T=100.

Note that there may be cases where the thickness of the joining layer 300 is not uniform over the entire joining layer 300 such as when an electrode terminal is embedded on the side of the surface 120 of the dielectric substrate 100 or when a groove is formed in a part of the surface 210 of the base plate 200. In such a case, a thickness of the joining layer 300 in a range excluding a portion where the thickness locally differs from other portions as described above may be defined as the “thickness of the joining layer 300” to be represented by T.

The joining layer 300 has a small Young's modulus (modulus of longitudinal elasticity) as compared to the dielectric substrate 100 and the base plate 200. Even when a difference in thermal expansion is generated between the dielectric substrate 100 and the base plate 200, since the joining layer 300 deforms and absorbs the difference in thermal expansion, thermal stress in the dielectric substrate 100 and the like can be kept small.

The Young's modulus of the joining layer 300 changes in accordance with a temperature of the joining layer 300. Hereinafter, a numerical value representing the Young's modulus of the joining layer 300 when the temperature of the joining layer 300 is −100° C. in units of “MPa” will be notated as “E”. For example, when the Young's modulus of the joining layer 300 at −100° C. is 0.01 GPa, E=10. Note that the temperature “−100° C.” described above is a criterion for the sake of convenience in order to specify a physical property (Young's modulus) of the joining layer 300 and does not limit a temperature of a refrigerant that is actually supplied to the refrigerant flow path 250 in any way.

In recent years, with an increase in energy incident to the substrate W during processing and the like, there is a tendency to demand higher cooling performance of the base plate 200 than ever before. For example, a refrigerant at −60° C. or a lower temperature may be supplied to the refrigerant flow path 250 of the base plate 200. Since the temperature of the refrigerant further drops with higher outputs of plasma, there is a possibility that refrigerants at around −100° C. may be supplied in the future.

A large thermal stress is applied to the dielectric substrate 100 due to a temperature change in respective sections, a temperature difference between the dielectric substrate 100 and the base plate 200, and the like which accompany the start of processing of the substrate W. In particular, thermal stress readily concentrates in an outlet portion of the gas hole 140 in the dielectric substrate 100 and damage to the dielectric substrate 100 may possibly occur with the portion as a point of origin of the damage.

Using a material with the lowest possible Young's modulus as the material of the joining layer 300 enables thermal stress that is applied to the dielectric substrate 100 to be reduced. However, in consideration of heat-transfer performance and the like that are required of the joining layer 300, a Young's modulus of the joining layer 300 cannot be reduced in an unlimited manner. The material of the joining layer 300 must be appropriately selected in consideration of required heat-transfer performance and the like under the condition that the Young's modulus is equal to or lower than a predetermined upper limit value.

Since the thicker the thickness (T) of the joining layer 300, the smaller the thermal stress applied to the dielectric substrate 100, an upper limit value of a Young's modulus (E) that is acceptable increases. In this manner, the thickness (T) of the joining layer 300 and the upper limit value of the Young's modulus (E) at −100° C. of the joining layer 300 are parameters that are correlated to each other. Various experiments, analyses, and the like carried out by the present inventors have led to a new finding with respect to the correlation as described below.

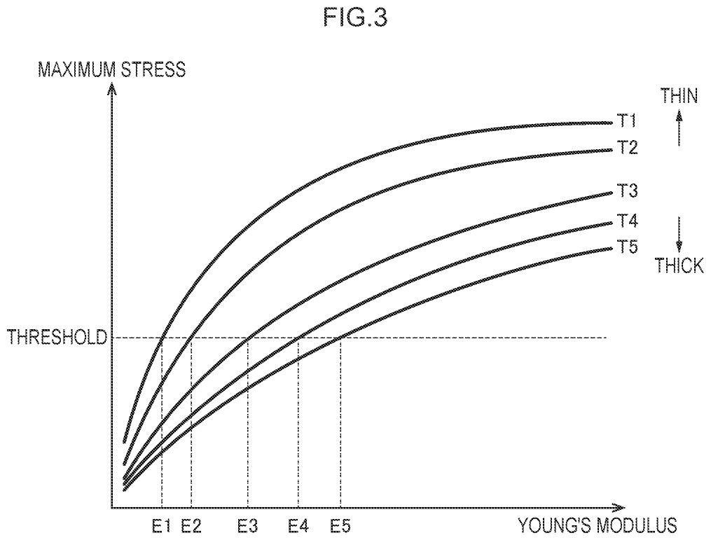

Five graphs shown in FIG. 3 represent a relationship between the Young's modulus of the joining layer 300 at −100° C. (horizontal axis) and a maximum stress that is generated in the dielectric substrate 100 (vertical axis) for each thickness (T1 to T5) of the joining layer 300. The Young's modulus of the horizontal axis is an individual value of “E” described earlier and “T1”, “T5”, and the like are individual values of “T” described earlier.

Each graph in FIG. 3 is obtained by changing a value of the Young's modulus (specifically, the Young's modulus at −100° C.) of the joining layer 300 and performing an analysis every time the value changes, and by plotting a maximum value of stress generated in the dielectric substrate 100 at a low temperature. Specifically, “at a low temperature” described above refers to when the temperature of the entire electrostatic chuck 10 is lowered to −100° C. after curing the joining layer 300 in a state where the temperature of the entire electrostatic chuck 10 is 40° C. In all of the analyses, a portion of the dielectric substrate 100 calculated to be subjected to a highest thermal stress was the portion in the vicinity of the end on the side of the surface 110 of the gas hole 140 arranged on the outermost circumference.

Character strings such as “T1” and “T2” attached to a right side of the respective graphs represent a thickness of the joining layer 300. Among the character strings, T1 is thinnest and T5 is thickest.

FIG. 3 reveals that as the Young's modulus of the joining layer 300 increases, the maximum stress generated in the dielectric substrate 100 at a low temperature increases. In addition, a comparison under a condition of a same Young's modulus of the joining layer 300 reveals that as the thickness of the joining layer 300 decreases, the maximum stress generated in the dielectric substrate 100 at a low temperature increases.

A “threshold” indicated on the vertical axis in FIG. 3 refers to an upper limit value of a range of maximum stress in which damage does not occur in the dielectric substrate 100.

“E1” in FIG. 3 is a value of the Young's modulus (E) at which the value of the maximum stress equals the threshold described above in the electrostatic chuck 10 in which the thickness of the joining layer 300 is “T1”. “E2” is a value of the Young's modulus (E) at which the value of the maximum stress equals the threshold described above in the electrostatic chuck 10 in which the thickness of the joining layer 300 is “T2”. “E3”, “E4”, and “E5” likewise represent similar values. Each of E1 to E5 can be described as an upper limit value of a range that is acceptable as a value of the “Young's modulus at −100° C.” in order to prevent damage to the dielectric substrate 100 from occurring. Such an upper limit value of the Young's modulus will also be referred to as an “acceptable Young's modulus” below. As is apparent from FIG. 3, the acceptable Young's modulus (E1 to E5) assumes a different value in accordance with the thickness (T1 to T5) of the joining layer 300.

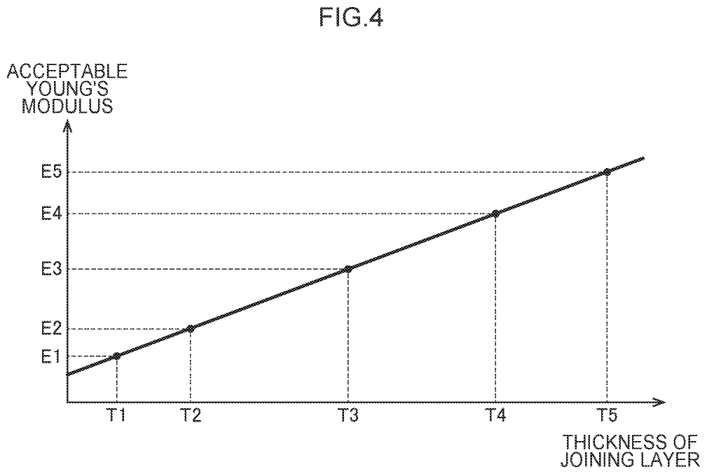

FIG. 4 shows a correspondence relationship between T1 to T5 (horizontal axis) which are the thickness of the joining layer 300 and E1 to E5 (vertical axis) which are the acceptable Young's modulus. As shown in FIG. 4, it is revealed that, generally, there is a first-order correlation between the thickness of the joining layer 300 and the acceptable Young's modulus. The first-order correlation shown in FIG. 4 can be represented by Expression (1) below.

$$( Acceptable Young ’ s modulus ) = 0.04 \times ( thickness of joining layer 300 ) - 0.04 \qquad ( 1 )$$

Therefore, if E denoting the Young's modulus of the joining layer 300 at −100° C. and T denoting the thickness of the joining layer 300 satisfy a condition indicated by Expression (2) below, the value of the maximum stress generated in the dielectric substrate 100 is held to or below the “threshold” shown in FIG. 3 and damage to the dielectric substrate 100 is to be reliably prevented.

$$E \leq 0.04 \times T - 0.04 \qquad ( 2 )$$

As described above, due to analyses and the like conducted by the present inventors, Expression (2) above has been obtained as a condition to obtain an appropriate thickness and an appropriate Young's modulus of the joining layer 300. By selecting the thickness and the Young's modulus of the joining layer 300 so as to satisfy the condition of Expression (2) above, thermal stress in the dielectric substrate 100 during processing of the substrate W and the like can be reduced to a level at which damage does not occur. Specific values of E and T may be appropriately selected as values within a range which satisfies required specifications such as heat-transfer performance that is required of the joining layer 300 and which also satisfies the condition of (2) above.

The findings described above are particularly useful in a case where a through hole such as the gas hole 140 is formed in the dielectric substrate 100 as in the present embodiment. In such a configuration, thermal stress tends to increase particularly in a portion of the through hole in a vicinity of the end on the side of the substrate W. However, analyses and the like have confirmed that by setting the thickness and the Young's modulus of the joining layer 300 so as to satisfy the condition of Expression (2) above, the thermal stress can be suppressed to a level at which damage to the dielectric substrate 100 does not occur even when a through hole is formed in the dielectric substrate 100.

It has been revealed that the smaller the diameter at an end of the through hole such as the gas hole 140 on an opposite side to the joining layer 300 (in other words, the end on the side of the surface 110), the larger the thermal stress that is generated in the dielectric substrate 100. A through hole designed to supply an inert gas such as the gas hole 140 is often a small hole with a diameter equal to or smaller than 0.2 mm in order to prevent a dielectric breakdown. However, analyses and the like have confirmed that by setting the thickness and the Young's modulus of the joining layer 300 so as to satisfy the condition of Expression (2) above, the thermal stress can be suppressed to a level at which damage to the dielectric substrate 100 does not occur even when the diameter of the through hole is equal to or smaller than 0.2 mm. Note that the description given above does not preclude making the diameter of the through hole equal to or larger than 0.2 mm in any way.

The thinner the joining layer 300, the larger the thermal stress that is applied to the dielectric substrate 100. However, even when the thickness of the joining layer 300 is reduced to 100 μm or less, by selecting the material of the joining layer 300 so as to satisfy the condition of Expression (2) above, the thermal stress can be suppressed to a level at which damage to the dielectric substrate 100 does not occur. In other words, according to the findings described above having been obtained by the present inventors, the thickness of the joining layer 300 can be suppressed to 100 μm or less which is thinner than ever before to prevent damage to the dielectric substrate 100 due to thermal stress while sufficiently enhancing heat-transfer performance in the joining layer 300. Note that the description given above does not preclude making the thickness of the joining layer 300 equal to or larger than 100 μm in any way.

Various types of adhesives can be used for the joining layer 300 as long as the condition of Expression (2) above can be satisfied. For example, besides a silicone adhesive as in the present embodiment, the joining layer 300 can be formed using various adhesives including an epoxy resin, a polyimide resin, an acrylic resin, and a modified silicone resin. However, since a silicone adhesive has a relatively small Young's modulus after curing, a silicone adhesive satisfying the condition of Expression (2) above can be readily selected from among various types of silicone adhesives. Therefore, the joining layer 300 is preferably a layer generated by curing a silicone adhesive as in the present embodiment.

While existing and commercially available off-the-shelf adhesives may be used as-is as the adhesive for forming the joining layer 300, an adhesive obtained by adjusting a Young's modulus of an existing adhesive so as to satisfy the condition of Expression (2) may be used. As methods of adjusting the Young's modulus of an adhesive, various known methods can be adopted. For example, by adding a functional group or a filler to the adhesive and respectively adjusting a type and/or an additive amount of the functional group and the filler, the Young's modulus in a low temperature range such as −100° C. can be changed and set to a desired value. As an example, when the adhesive is a silicone resin, particularly the Young's modulus in a low temperature range can be adjusted by adjusting an additive amount of a phenyl group. The Young's modulus can also be lowered by reducing an additive amount of an inorganic filler.

The present embodiment has been described above with reference to specific examples. However, it is to be understood that the present disclosure is not limited to the specific examples. Appropriate design modifications of the specific examples made by persons skilled in the art are also included in the scope of the present disclosure insofar as such modifications possess features of the present disclosure. The respective elements included in each specific example described above and arrangements, conditions, shapes, and the like of such elements are not limited to those exemplified and can be modified as appropriate. Combinations of the respective elements included in each specific example described above can be appropriately changed insofar as no technical contradictions arise from such changes.

What is claimed is:

1. An electrostatic chuck, comprising:
a dielectric substrate;
a base plate formed of a metal material; and
a joining layer which is provided between the dielectric substrate and the base plate, wherein
when a thickness of the joining layer is T (μm) and
a Young's modulus of the joining layer at −100° C. is E (MPa), a condition expressed as
$$E \leq 0.04 \times T - 0.04$$
is satisfied.

2. The electrostatic chuck according to claim 1, wherein a through hole is formed in the dielectric substrate.

3. The electrostatic chuck according to claim 2, wherein a diameter at an end of the through hole on an opposite side to the joining layer is equal to or smaller than 0.2 mm.

4. The electrostatic chuck according to claim 1, wherein the thickness of the joining layer is equal to or smaller than 100 μm.

5. The electrostatic chuck according to claim 1, wherein the joining layer is a layer generated by curing a silicone adhesive.
